(19) United States
(12) Patent Application Publication
(10) Pub. No.: US 2025/0344350 A1
(43) Pub. Date: Nov. 6, 2025

(54) THERMALLY CONDUCTIVE FOAM COOLING SYSTEM AND METHOD

(71) Applicant: Dell Products L.P., Round Rock, TX (US)

(72) Inventors: Robert J. Proulx, Holden, MA (US); Mauricio A. Sanchez, League City, TX (US)

(73) Assignee: Dell Products L.P., Round Rock, TX (US)

(21) Appl. No.: 18/652,133

(22) Filed: May 1, 2024

(51) Int. Cl. H05K 7/20

(52) U.S. Cl. CPC H05K 7/20463; H05K 7/20263; H05K 7/20272; H05K 7/20481

(57) ABSTRACT

Systems and methods are provided for component cooling using a thermally conductive foam that conforms to the shape of components on the electronic devices while providing adequate movement of heat away from their components. According to one embodiment, a thermally conductive foam cooling system includes a coolant pipe immersed in a foam block. The foam block has a surface with a contour that matches the contour of an electrical component. The coolant pipe is configured to pass a coolant fluid through the foam block, while the foam block is thermally conductive to convey heat from the electrical component to the coolant fluid.

### BACKGROUND

As the value and use of information continues to increase, individuals and businesses seek additional ways to process and store it. One option available to users is an Information Handling System (IHS). An IHS generally processes, compiles, stores, and/or communicates information or data for business, personal, or other purposes thereby allowing users to take advantage of the value of the information. Because technology and information handling needs and requirements vary between different users or applications, IHSs may also vary regarding what information is handled, how the information is handled, how much information is processed, stored, or communicated, and how quickly and efficiently the information may be processed, stored, or communicated.

IHSs may be general or configured for a specific user or specific use, such as financial transaction processing, airline reservations, enterprise data storage, or global communications. In addition, IHSs may include a variety of hardware and software components that may be configured to process, store, and communicate information and may include one or more computer systems, data storage systems, and networking systems.

In recent years, as IHS components such as processors, graphics cards, random access memory (RAM), etc. have increased in clock speed and power consumption, the amount of heat produced by such components during normal operation has also increased. Often, the temperatures of these components need to be kept within a selected range to prevent overheating, instability, malfunction, and damage leading to a shortened component lifespan. Accordingly, cooling systems are often implemented in IHSs to cool certain high heat generating components.

To control the temperature of components of an IHS, one approach has been to implement a “passive” cooling system that serves to reject heat of a component by an airflow driven by one or more system-level air movers (e.g., fans, blowers, etc.). A different approach may include using an “active” cooling system in which a heat-exchanging cold plate is thermally coupled to one or more portions of the IHS, while a chilled liquid is passed through conduits internal to the cold plate to remove heat from those components.

### SUMMARY

Systems and methods are provided for component cooling using a thermally conductive foam that conforms to the shape of components on the electronic devices while providing adequate movement of heat away from their components. According to one embodiment, a thermally conductive foam cooling system includes a coolant pipe immersed in a foam block. The foam block has a surface with a contour that matches the contour of an electrical component. The coolant pipe is configured to pass a coolant fluid through the foam block, while the foam block is thermally conductive to convey heat from the electrical component to the coolant fluid.

According to another embodiment, a cooling method includes the steps of pouring an amorphous material over an electrical component, and immersing a coolant pipe within the amorphous material. When the amorphous material cures into a foam block, the foam block has a surface with a contour that matches the contour of the electrical component.

According to yet another embodiment, a cooling method includes the steps of immersing a coolant pipe in a foam sheet with multiple edges, attaching a cover sheet to a portion of the edges of the foam sheet, and inserting an electrical component inside of the pouch through the opening. The attached cover sheet and foam sheet forms a pouch with an opening.

### BRIEF DESCRIPTION OF THE DRAWINGS

The present invention(s) is/are illustrated by way of example and is/are not limited by the accompanying figures, in which like references indicate similar elements. Elements in the figures are illustrated for simplicity and clarity, and have not necessarily been drawn to scale.

FIGS. 1A and 1B illustrate an example thermally conductive foam cooling system that may provide a solution to the aforementioned problems with cooling systems for electrical components according to one embodiment of the present disclosure.

FIGS. 2A-2D illustrate another example thermally conductive foam cooling system according to one embodiment of the present disclosure.

FIGS. 3A-C illustrate an example simulation results that may be obtained via the use of the foam cooling system of FIGS. 2A-D.

FIG. 4 illustrates another example thermally conductive foam cooling system according to one embodiment of the present disclosure.

FIG. 5 illustrates yet another example thermally conductive foam cooling system according to one embodiment of the present disclosure.

FIG. 6 is a block diagram of certain components of an example IHS, which may use the thermally conductive foam cooling system described herein above.

### DETAILED DESCRIPTION

The present disclosure is described with reference to the attached figures. The figures are not drawn to scale, and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

An IHS may include Random Access Memory (RAM), one or more processing resources such as a Central Processing Unit (CPU) or hardware or software control logic, Read-Only Memory (ROM), and/or other types of nonvolatile memory. Additional components of an IHS may include one or more disk drives, one or more network ports for communicating with external devices as well as various I/O devices, such as a keyboard, a mouse, touchscreen, and/or a video display. An IHS may also include one or more buses operable to transmit communications between the various hardware components.

IHSs typically include system memory for storage of data and program code that the system's processor(s) may execute. Today's IHS designs have migrated toward the use of system memory in the form of dual inline memory modules (DIMMs) that can be coupled to a motherboard of the IHS using DIMM electrical connectors that are mechanically fixed to the motherboard. Each DIMM may include a DIMM printed circuit board (PCB) that includes multiple electrical contacts that electrically couple the components (e.g., Dynamic Random-Access Memory (DRAM)) on the DIMM PCB to the components on the motherboard.

Nevertheless, several factors exist to make cooling DIMMs challenging. For one reason, relatively little latitude in the form factor of DIMMs is available as their geometry is heavily specified by Joint Electron Device Engineering Council (JEDEC) to maintain interoperability among vendors. Additionally, density is prioritized as there is relatively little space between DIMMs. For example, many motherboards are designed to have a DIMM spacing of approximately 0.30 inches; thus, resulting in little room (e.g., 4 millimeters) between DRAM components on adjacent DIMMs. As such, there is not enough spacing to add a finned airflow solution. The relatively little spacing also forms a pressure drop when air cooling is utilized.

Solutions are limited due to the fact that DIMMs need to be serviceable. That is, they may need to be removed and replaced on the motherboard from time to time that often impacts the geometry and interface materials used. To allow DIMMs to be used in 1U servers, they are dimensioned to be short in order to keep the server within the confines of a 1U slot, and long so that they can support ten 10 DRAM components on the DIMM's PCB. Bulk temperature rise is also an issue, for the DRAM components at the tailing edge of airflow across the DIMM's surface. Several different heights of components exist on a typical DIMM PCB, thus making heat sink solutions challenging as different gap pad materials with different thicknesses may be needed.

Yet another factor may include the ever-increasing level of heat load generated by DIMMs. For example, next generation DIMMs are expected to dissipate up to 20 Watts. In general, the approach for air cooling is to increase the airflow, but the airflow required can significantly increase fan usage and power consumption.

In the air-cooled space, attaching a cooling foil or slab to the DRAM components of the DIMMs has been considered. This approach adds some heat transfer area and spreads the heat from the hottest DRAM component toward cooler components, but the impact is limited as any improvement may come at the cost of pressure drop. Other more elaborate finned concepts have been posited, but their size typically limits their use in the 2U space. Gains in heat transfer are often mostly undone by the negative impact of gap pads. In the liquid-cooled space, various systems involving cooling tubes and heat pipes have been proposed, but as with air cooled solutions, the effectiveness is often decreased by the impact of gap pads as described above.

In summary, to effectively cool DIMMs and similar electronic devices featuring bare components on PC boards, creating a strong thermal connection between its components and cooling medium is key. Additionally, the thermal connection should be thermally conductive, electrically isolating, and be able to contour around various devices, such as those components that may exist on DIMMs. As will be described in detail herein below, embodiments of the present disclosure provide systems and methods for component cooling using a thermally conductive foam that conforms to the shape of components on the electronic devices while providing adequate movement of heat away from their components.

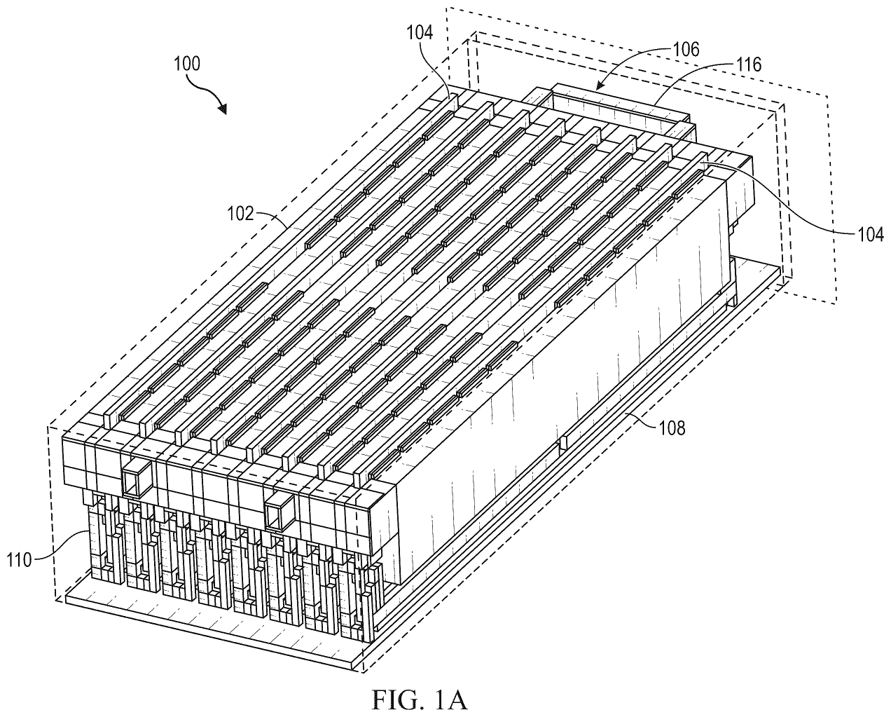

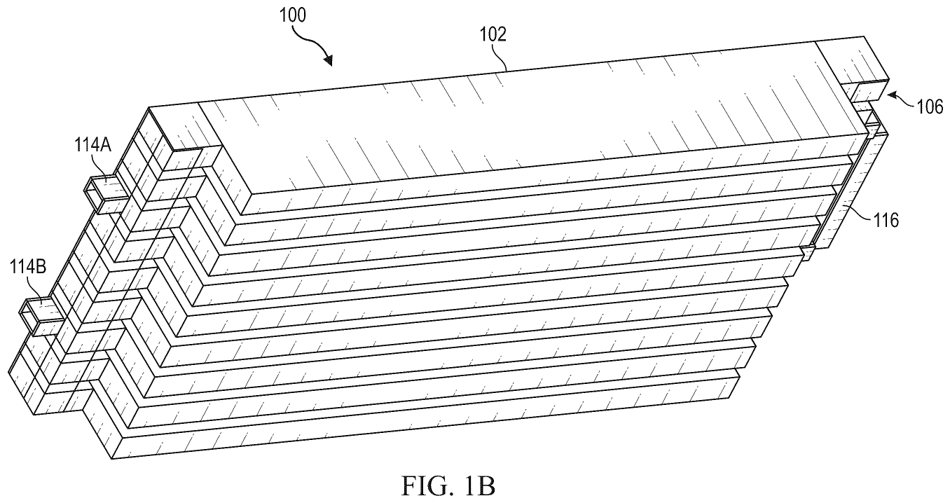

FIGS. 1A and 1B illustrate an example thermally conductive foam cooling system 100 that may provide a solution to the aforementioned problems with cooling systems for electrical components according to one embodiment of the present disclosure. The thermally conductive foam cooling system 100 includes a foam block 102 formed around a group of DIMMs 104, and a coolant pipe 106 immersed within the foam block 102. A partial view of a motherboard 108 is shown on which DIMM connectors 110 are provided for electrically coupling the DIMMs 104 to the motherboard 108. The block 102 is formed from an amorphous material that has been poured over the DIMMs 102 and coolant pipe 106 and allowed to harden into its cured form. Because amorphous material is poured over the DIMMs 102 and pipe 106, it has a surface with a contour that matches the contour of the DIMMs 104. That is, the block 102 possesses relatively good contact with both of the DIMMs 102 and pipe 106 after being cured. The block 102 is also sufficiently deformable to allow it to be removed from the DIMMs 102 with a relatively small separating action. For example, FIG. 1A shows the block 102 being mounted over the DIMMs 104, while FIG. 1B shows the block 102 as having been removed from the DIMMs 104.

The pipe 106 is generally rigid in shape and has a thin profile in order to fit between adjacent DIMMs 106. The pipe 106 may be made of any suitable material that is sufficiently thermally conductive and structurally sound. Examples of such materials may include copper, aluminum, brass, lead, zinc, and the like. When coolant (e.g., water) is run through the pipe 106, it absorbs heat generated by the DIMMs 106. The cured foam block 102 possesses relatively good thermally conductive properties so that it can convey heat from the DIMMs 104 to the pipe 106. One example of such a material may include a moldable foam that has a thermal conductivity of approximately 10 Watts/mK, and is available from Laird Technologies, in Islip, New York. As shown, the pipe 106 has two linear sections 114a-b that extend through the block 102 and are connected together via a manifold 116. Nevertheless, it should be appreciated that any quantity of linear sections, such as three or more linear sections.

The foam cooling system 100 may be made in any suitable manner. In one embodiment, in order to make the foam cooling system 100, the pipe 106 may be placed between the DIMMs 102, a form (not shown) or other structure may be placed around a group of DIMMs 102, and the amorphous material introduced around the DIMMs 102 and pipe 106. Once the amorphous material has been allowed to cure into a block 102, the form may be removed. In one embodiment, a mold release agent may be applied to the surface of the DIMMs 102 so that the amorphous material will not adhere to them. In another embodiment, an adhesive agent may be applied to the surface of the pipe 106 so that the amorphous material will adhere to it.

In one embodiment, the block 102 and pipe 106 may be formed using a 3-dimensional (3D) printing process, which may result in assembly and cost benefits. Additionally, with 3D printing, casing and pipe routing could potentially be altered for better thermal improvement when taken together with the placing of the foam.

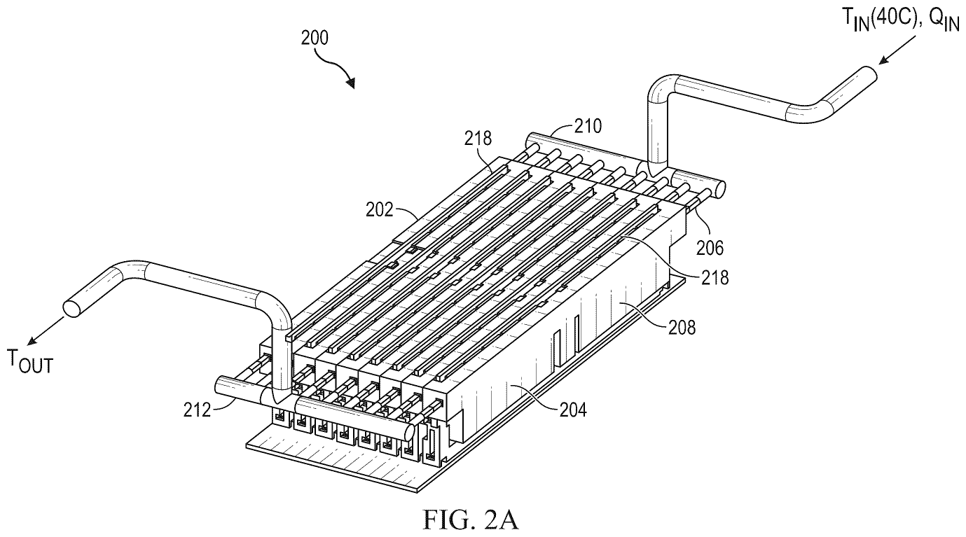

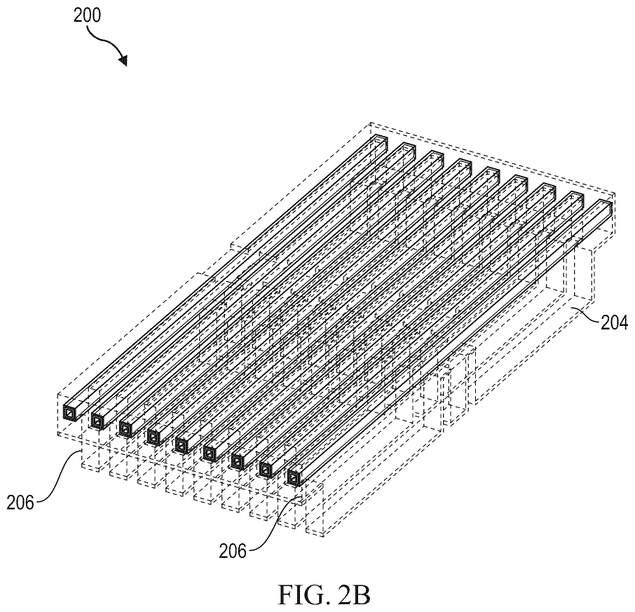

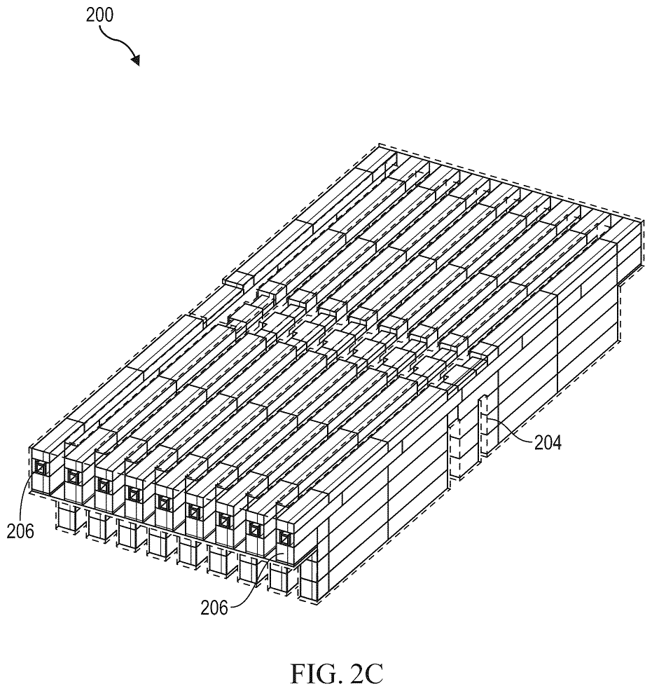

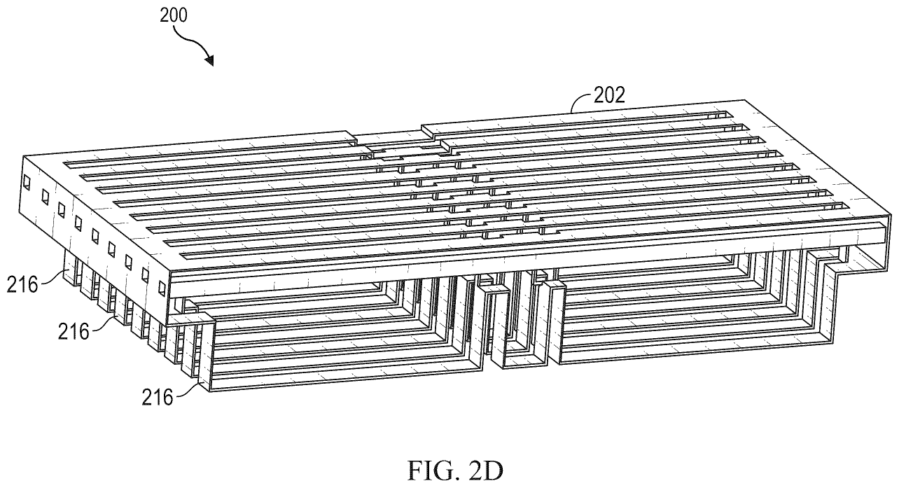

FIGS. 2A-2D illustrate another example thermally conductive foam cooling system 200 according to one embodiment of the present disclosure. As best shown in FIG. 2A, the system 200 includes a casing frame 202, a foam block 204, multiple coolant pipes 206 extending through the foam block 204, a graphite wrap 208 that covers the foam block 204 and casing frame 202, an input manifold 210 coupled to one end of the pipes 206, and an output manifold 212 coupled to the opposing end of the pipes 206. FIG. 2B illustrates the system 200 of FIG. 2A with the manifolds 210, 212 and DIMMs 218 removed, FIG. 2C illustrates the system 200 of FIG. 2B with the graphite wrap 208 removed, while FIG. 2D illustrates the system 200 of FIG. 2C with the foam block 204 and coolant pipes 206 removed to show only the casing frame 202.

The casing frame 202 provides a relatively sturdy structure for the foam block 204, and is configured with slots 216 into which the DIMMs 218 may be inserted. The casing frame 202 may be made from any structurally rigid material, such as aluminum. To build the system 200, the casing frame 202 may be placed over the DIMMs 218 through the slots 216. The coolant pipes 206 may be inserted between adjacent DIMMs 218. Like the coolant pipes 106 of FIGS. 2A-B, the coolant pipes 206 may be sufficiently thin to fit between adjacent DIMMs 218, and be made of any material that is sufficiently thermally conductive and structurally sound. Next, the amorphous material may be poured into and around casing frame 202, DIMMs 218, and coolant pipes 206. In one embodiment, a molding form (not shown) or other structure may be placed around the casing frame 202 while the amorphous material is curing, and removed once the amorphous material has hardened into the foam block 204. A mold release agent may be applied to the DIMMs 218 so that they do not adhere to the amorphous material, and an adhesive agent may be applied to the casing frame 202 and coolant pipes 206 so that they do adhere to the foam block 204 when hardened.

Once the amorphous material has hardened into the foam block 204, the graphite wrap 208, which may be provided by an elongated section of graphite tape, may be wrapped around the casing frame 202, foam block 204 assembly. The graphite wrap 208 may be used to exert a compacting force on the foam block 204 to ensure good contact with the DIMMs 218, and to improve heat movement away from the DIMMs 218. Additionally, the input manifold 210 and output manifold 212 may be coupled to opposing ends of the coolant pipes 206 using any suitable adhesive, such as weldment, soldering, sweating, or polymer adhesive (e.g., epoxy glue, silicon glue, etc.).

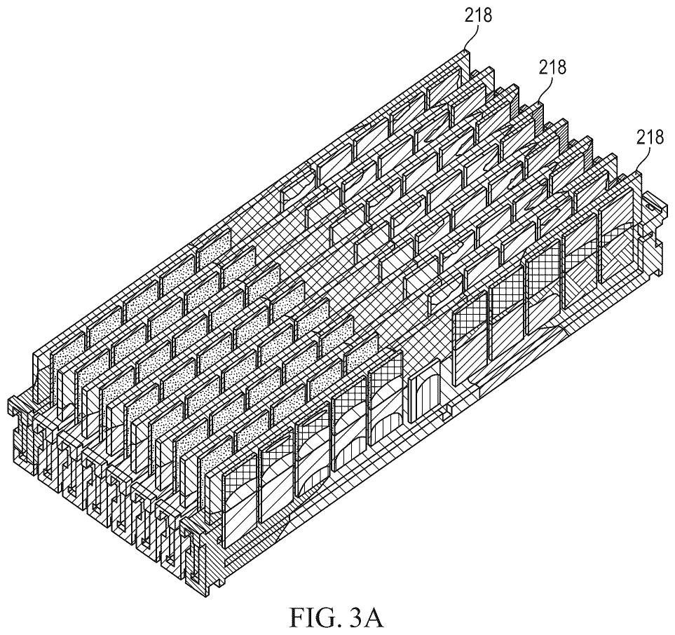

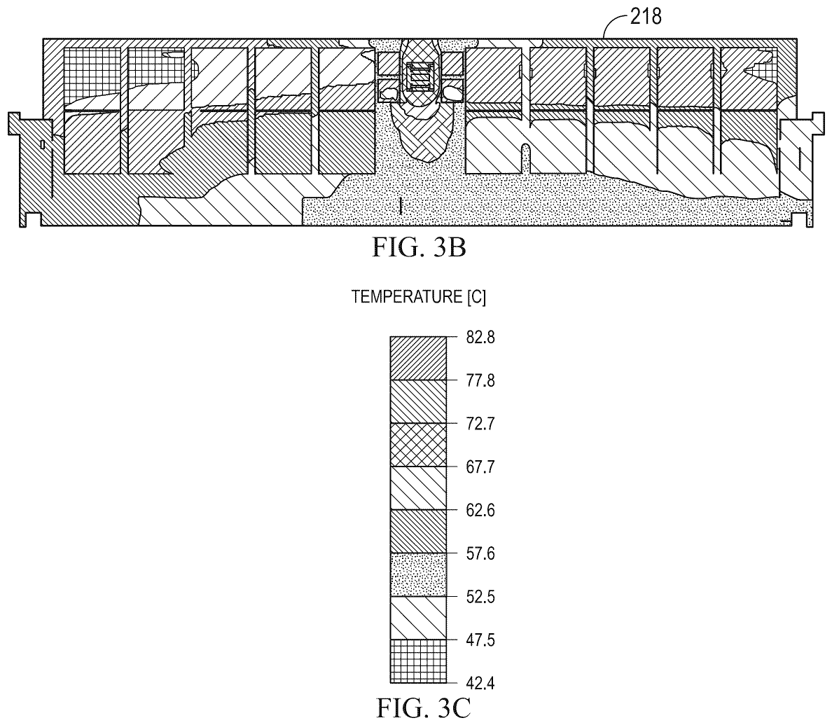

FIGS. 3A-C illustrate an example simulation results that may be obtained via the use of the foam cooling system 200 of FIGS. 2A-D. In particular, FIG. 3A is a perspective view of the DIMMs 218, and FIG. 3B is an elevational view of the DIMMs 218 shown in operation and generating heat. FIG. 3C illustrates a temperature indicator showing a range of temperatures that the DIMMs 218 could potentially be at during the simulation.

The simulation shows that when the DIMMs 218 are operating at a typical load levels and coolant at 40.0 degrees Celsius is fed through the manifolds 210, 212 and coolant pipes 206 at 0.5 Liters-per-minute (L/min), the maximum DRAM temperature gets to 58 degrees Celsius. The test results are particularly good given that the maximum temperature rating for most DRAM chips is approximately 85 degrees Celsius.

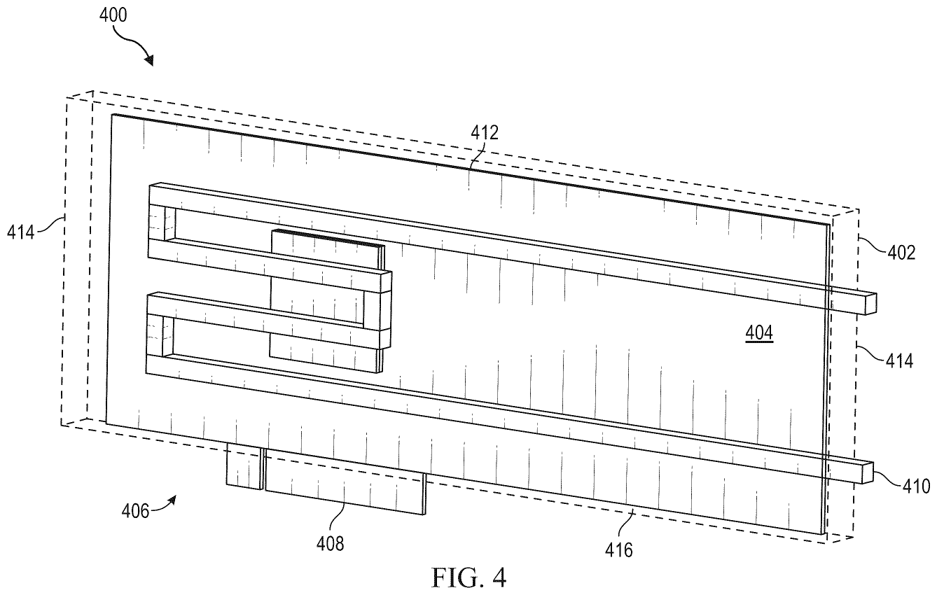

FIG. 4 illustrates another example thermally conductive foam cooling system 400 according to one embodiment of the present disclosure. The system 400 generally includes a foam sheet 402 onto which another cover sheet 404 may be attached in order to form a pouch 406 into which a component 408, which in this particular example embodiment, is a PCIe card, may be placed. A coolant pipe 410 is embedded in the sheet 402 to convey a coolant for removing the heat imparted onto the foam sheet 402 by the component.

In one embodiment, the foam sheet 402 may be formed by pouring an amorphous material over the component 408 such that the amorphous material may become the foam sheet 402 when cured.

The cover sheet 404 may be attached to foam sheet 402 across at least a portion of a top edge 412 and two side edges 414 while the bottom edge 416 is left un-attached so that the component 408 may be inserted into and removed out of the pouch 406. The foam sheet 402 may be made from an amorphous foam material that is similar in design to the amorphous material described herein above. The foam sheet 402 be any suitable height and width to allow insertion of the component 408; that is, it may have a height and width slightly larger than the component 408 that it is to cool. Additionally, the foam sheet 402 may have any thickness that sufficiently conveys heat generated by the component 408 to the coolant pipe 410. To provide a particular example, the foam sheet 402 may have a thickness ranging from ⅛ inch to ½ inch thick.

The coolant pipe 410 may be made of a similar material that the coolant pipe 106 of FIGS. 1A-D is formed. In one embodiment, the coolant pipe 410 may be made of a flexible polymer material, such as vinyl or silicon, so that the foam sheet 402 may bend around the contour of the surface of the component 408. In other embodiments, the coolant pipe 410 may be formed from a relatively rigid material, such as brass or copper, so that the foam sheet 402 may maintained at a relatively flat shape when held against the surface of the component 408.

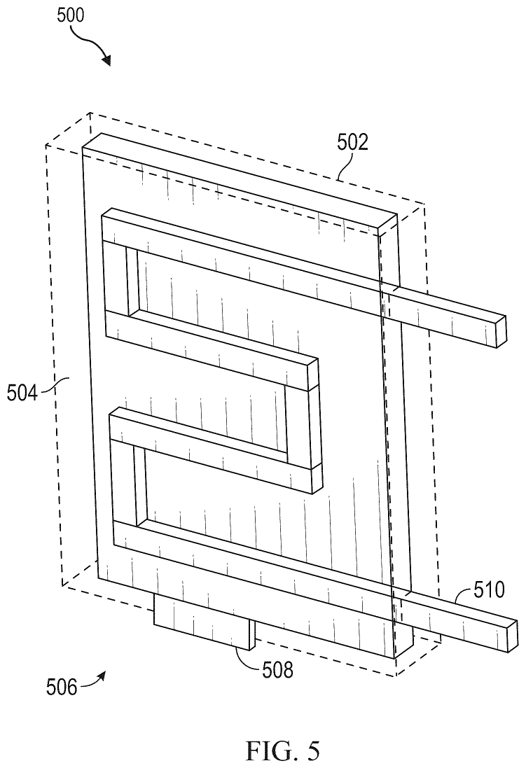

FIG. 5 illustrates yet another example thermally conductive foam cooling system 500 according to one embodiment of the present disclosure. The system 500 includes a foam sheet 502, a cover sheet 504 that are attached in order to form a pouch 506, and a coolant pipe 510 that are similar in design and construction to the foam sheet 402, cover sheet 404, pouch 406, and coolant pipe 410 of FIG. 4. The system 500 of FIG. 5 is different, however, in that it is sized to allow insertion of an E3. Short drive component 508. Thus as can be seen, differing sized systems 500, 600 may be created for providing cooling for correspondingly differing sized components 408, 508.

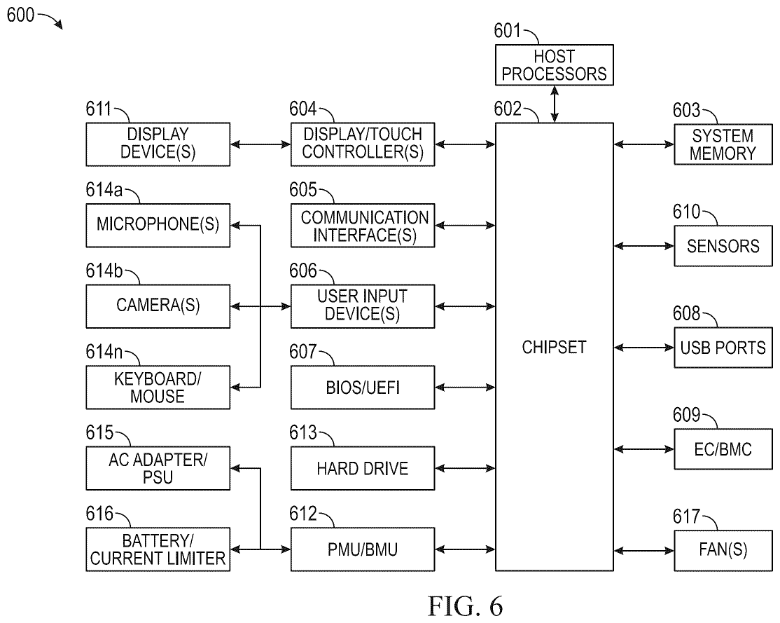

FIG. 6 is a block diagram of certain components of an example IHS 600, which may use the thermally conductive foam cooling system described herein above. As depicted, IHS 600 includes host processor(s) 601. In various embodiments, IHS 600 may be a single-processor system, a multi-processor system including two or more processors, and/or a heterogeneous computing platform. Host processor(s) 601 may include any processor capable of executing program instructions, such as a PENTIUM processor, or any general-purpose or embedded processor implementing any of a variety of Instruction Set Architectures (ISAs), such as an ×86 or a Reduced Instruction Set Computer (RISC) ISA (e.g., POWERPC, ARM, SPARC, MIPS, etc.).

IHS 600 includes chipset 602 coupled to host processor(s) 601. Chipset 602 may provide host processor(s) 601 with access to several resources. In some cases, chipset 602 may utilize a QuickPath Interconnect (QPI) bus to communicate with host processor(s) 601.

Chipset 602 may also be coupled to communication interface(s) 605 to enable communications between IHS 600 and various wired and/or wireless networks, such as Ethernet, WiFi, BLUETOOTH (BT), cellular or mobile networks (e.g., Code-Division Multiple Access or “CDMA,” Time-Division Multiple Access or “TDMA,” Long-Term Evolution or “LTE,” etc.), satellite networks, or the like.

Communication interface(s) 605 may also be used to communicate with certain peripherals devices (e.g., BT speakers, microphones, headsets, etc.). Moreover, communication interface(s) 605 may be coupled to chipset 602 via a Peripheral Component Interconnect Express (PCIe) bus, or the like.

Chipset 602 may be coupled to display/touch controller(s) 604, which may include one or more Graphics Processor Units (GPUs) on a graphics bus, such as an Accelerated Graphics Port (AGP) or PCIe bus. As shown, display/touch controller(s) 604 provide video or display signals to one or more display device(s) 611.

Display device(s) 611 may include Liquid Crystal Display (LCD), Light Emitting Diode (LED), organic LED (OLED), or other thin film display technologies. Display device(s) 611 may include a plurality of pixels arranged in a matrix, configured to display visual information, such as text, two-dimensional images, video, three-dimensional images, etc. In some cases, display device(s) 611 may be provided as a single continuous display, or as two or more discrete displays.

Chipset 602 may provide host processor(s) 601 and/or display/touch controller(s) 604 with access to system memory 603. In various embodiments, system memory 603 may be implemented using any suitable memory technology, such as static RAM (SRAM), dynamic RAM (DRAM) or magnetic disks, or any nonvolatile/Flash-type memory, such as a solid-state drive (SSD) or the like.

Chipset 602 may also provide host processor(s) 601 with access to one or more Universal Serial Bus (USB) ports 608, to which one or more peripheral devices may be coupled (e.g., integrated or external webcams, microphones, speakers, etc.).

Chipset 602 may further provide host processor(s) 601 with access to one or more hard disk drives, solid-state drives, optical drives, or other removable-media drives 613.

Chipset 602 may also provide access to one or more user input devices 606, for example, using a super I/O controller or the like. Examples of user input devices 606 may include, but are not limited to, microphone(s) 614A, camera(s) 614B, and keyboard/mouse 614N. Other user input devices 606 may include a touchpad, trackpad, stylus or active pen, totem, etc.

Each user input devices 606 may include a respective controller (e.g., a touchpad may have its own touchpad controller) that interfaces with chipset 602 through a wired or wireless connection (e.g., via communication interfaces(s) 605). In some cases, chipset 602 may also provide access to one or more user output devices (e.g., video projectors, paper printers, 3D printers, loudspeakers, audio headsets, Virtual/Augmented Reality (VR/AR) devices, etc.). In certain embodiments, chipset 602 may further provide an interface for communications with hardware sensors 610.

Sensors 610 may be disposed on or within the chassis of IHS 600, or otherwise coupled to IHS 600, and may include, but are not limited to: electric, magnetic, radio, optical (e.g., camera, webcam, etc.), infrared, thermal (e.g., thermistors etc.), force, pressure, acoustic (e.g., microphone), ultrasonic, proximity, position, deformation, bending, direction, movement, velocity, rotation, gyroscope, Inertial Measurement Unit (IMU), and/or acceleration sensor(s).

The Unified Extensible Firmware Interface (UEFI) was designed as a successor to BIOS. As a result, many modern IHSs utilize UEFI in addition to or instead of a BIOS. As used herein, BIOS 607 is intended to also encompass a UEFI component.

Embedded Controller (EC) or Baseboard Management Controller (BMC) 609 is operational from the very start of each IHS power reset and handles various tasks not ordinarily handled by host processor(s) 601. Examples of these operations may include, but are not limited to: receiving and processing signals from a keyboard or touchpad, as well as other buttons and switches (e.g., power button, laptop lid switch, etc.), receiving and processing thermal measurements (e.g., performing fan control, CPU and GPU throttling, and emergency shutdown), controlling indicator LEDs (e.g., caps lock, scroll lock, number lock, battery, power, wireless LAN, sleep, etc.), managing PMU/BMU 612, alternating current (AC) adapter/Power Supply Unit (PSU) 615 and/or battery/current limiter 616, allowing remote diagnostics and remediation over network(s), etc. For example, EC/BMC 609 may implement operations for interfacing with power adapter/PSU 615 in managing power for IHS 600. Such operations may be performed to determine the power status of IHS 600, such as whether IHS 600 is operating from AC adapter/PSU 615 and/or battery 616.

Firmware instructions utilized by EC/BMC 609 may also be used to provide various core operations of IHS 600, such as power management and management of certain modes of IHS 600 (e.g., turbo modes, maximum operating clock frequencies of certain components, etc.). In addition, EC/BMC 609 may implement operations for detecting certain changes to the physical configuration or posture of IHS 600. For instance, when IHS 600 is embodied as a 2-in-1 laptop/tablet form factor, EC/BMC 609 may receive inputs from a lid position or hinge angle sensor 610, and it may use those inputs to determine: whether the two sides of IHS 600 have been latched together to a closed position or a tablet position, the magnitude of a hinge or lid angle, etc. In response to these changes, the EC may enable or disable certain features of IHS 600 (e.g., front or rear facing camera, etc.).

In some cases, EC/BMC 609 may be configured to identify any number of IHS postures, including, but not limited to: laptop, stand, tablet, tent, or book. For example, when display(s) 611 of IHS 600 is open with respect to a horizontal keyboard portion, and the keyboard is facing up, EC/BMC 609 may determine IHS 600 to be in a laptop posture. When display(s) 611 of IHS 600 is open with respect to the horizontal keyboard portion, but the keyboard is facing down (e.g., its keys are against the top surface of a table), EC/BMC 609 may determine IHS 600 to be in a stand posture.

When the back of display(s) 611 is closed against the back of the keyboard portion, EC/BMC 609 may determine IHS 600 to be in a tablet posture. When IHS 600 has two display(s) 611 open side-by-side, EC/BMC 609 may determine IHS 600 to be in a book posture. When IHS 600 has two displays open to form a triangular structure sitting on a horizontal surface, such that a hinge between the displays is at the top vertex of the triangle, EC/BMC 609 may determine IHS 600 to be in a tent posture. In some implementations, EC/BMC 609 may also determine if display(s) 611 of IHS 600 are in a landscape or portrait orientation. In some cases, EC/BMC 609 may be installed as a Trusted Execution Environment (TEE) component to the motherboard of IHS 600.

Additionally, or alternatively, EC/BMC 609 may be configured to calculate hashes or signatures that uniquely identify individual components of IHS 600. In such scenarios, EC/BMC 609 may calculate a hash value based on the configuration of a hardware and/or software component coupled to IHS 600. For instance, EC/BMC 609 may calculate a hash value based on all firmware and other code or settings stored in an onboard memory of a hardware component.

Hash values may be calculated as part of a trusted process of manufacturing IHS 600 and may be maintained in secure storage as a reference signature. EC/BMC 609 may later recalculate the hash value for a component, compare it against the reference hash value to determine if any modifications have been made to the component, thus indicating that the component has been compromised. In this manner, EC/BMC 609 may validate the integrity of hardware and software components installed in IHS 600.

In various embodiments, IHS 600 may be coupled to an external power source (e.g., AC outlet or mains) through an AC adapter/PSU 615. AC adapter/PSU 615 may include an adapter portion having a central unit (e.g., a power brick, wall charger, or the like) configured to draw power from an AC outlet via a first electrical cord, convert the AC power to direct current (DC) power, and provide DC power to IHS 600 via a second electrical cord.

Additionally, or alternatively, AC adapter/PSU 615 may include an internal or external power supply portion (e.g., a switching power supply, etc.) connected to the second electrical cord and configured to convert AC to DC. AC adapter/PSU 615 may also supply a standby voltage, so that most of IHS 600 can be powered off after preparing for hibernation or shutdown, and powered back on by an event (e.g., remotely via wake-on-LAN, etc.). In general, AC adapter/PSU 615 may have any specific power rating, measured in volts or watts, and any suitable connectors.

IHS 600 may also include internal or external battery 616. Battery 616 may include, for example, a Lithium-ion or Li-ion rechargeable device capable of storing energy sufficient to power IHS 600 for an amount of time, depending upon the IHS's workloads, environmental conditions, etc. In some cases, a battery pack may also contain temperature sensors, voltage regulator circuits, voltage taps, and/or charge-state monitors. For example, battery 616 may include a current limiter, or the like.

In some embodiments, battery 616 may be configured to detect overcurrent or undervoltage conditions using Limits Management Hardware (LMH). As used herein, the term “overcurrent” refers to a condition in an electrical circuit that arises when a normal load current is exceeded (e.g., overloads, short circuits, etc.). Conversely, the term “undervoltage” refers to a condition (e.g., “brownout”) where the applied voltage drops to X % of rated voltage (e.g., 90%), or less, for a predetermined amount of time (e.g., 1 minute).

Power Management Unit (PMU) 612 governs power functions of IHS 600, including AC adapter/PSU 615 and battery 616. For example, PMU 612 may be configured to: monitor power connections and battery charges, charging batteries, control power to other components, devices, or ICs, shut down components when they are left idle, control sleep and power functions (On and Off), managing interfaces for built-in keypad and touchpads, regulate real-time clocks (RTCs), etc.

In some implementations, PMU 612 may include one or more Power Management Integrated Circuits (PMICs) configured to control the flow and direction or electrical power in IHS 600. Particularly, a PMIC may be configured to perform battery management, power source selection, voltage regulation, voltage supervision, undervoltage protection, power sequencing, and/or charging operations. It may also include a DC-to-DC converter to allow dynamic voltage scaling, or the like.

Additionally, or alternatively, PMU 612 may include a Battery Management Unit (BMU) (referred to collectively as “PMU/BMU 612”). AC adapter/PSU 615 may be removably coupled to a battery charge controller within PMU/BMU 612 to provide IHS 600 with a source of DC power from battery cells within battery 616 (e.g., a lithium ion (Li-ion) or nickel metal hydride (NiMH) battery pack including one or more rechargeable batteries). PMU/BMU 612 may include non-volatile memory and it may be configured to collect and store battery status, charging, and discharging information, and to provide that information to other IHS components.

Examples of information collected and stored in a memory within PMU/BMU 612 may include, but are not limited to: operating conditions (e.g., battery operating conditions including battery state information such as battery current amplitude and/or current direction, battery voltage, battery charge cycles, battery state of charge, battery state of health, battery temperature, battery usage data such as charging and discharging data; and/or IHS operating conditions such as processor operating speed data, system power management and cooling system settings, state of “system present” pin signal), environmental or contextual information (e.g., such as ambient temperature, relative humidity, system geolocation measured by GPS or triangulation, time and date, etc.), and BMU events.

Examples of BMU events may include, but are not limited to acceleration or shock events, system transportation events, exposure to elevated temperature for extended time periods, high discharge current rate, combinations of battery voltage, battery current and/or battery temperature (e.g., elevated temperature event at full charge and/or high voltage causes more battery degradation than lower voltage), etc.

In some embodiments, power draw measurements may be conducted with control and monitoring of power supply via PMU/BMU 612. Power draw data may also be monitored with respect to individual components or devices of IHS 600. Whenever applicable, PMU/BMU 612 may administer the execution of a power policy, or the like.

IHS 600 may also include one or more fans 617 configured to cool down one or more components or devices of IHS 600 disposed inside a chassis, case, or housing. Fan(s) 617 may include any fan inside, or attached to, IHS 600 and used for active cooling. Fan(s) 617 may be used to draw cooler air into the case from the outside, expel warm air from inside, and/or move air across a heat sink to cool a particular IHS component. In various embodiments, both axial and sometimes centrifugal (blower/squirrel-cage) fans may be used.

In other embodiments, IHS 600 may not include all the components shown in FIG. 6. In other embodiments, IHS 600 may include other components in addition to those that are shown in FIG. 6. Furthermore, some components that are represented as separate components in FIG. 6 may instead be integrated with other components, such that all or a portion of the operations executed by the illustrated components may instead be executed by the integrated component.

For example, in various embodiments described herein, host processor(s) 601 and/or other components of IHS 600 (e.g., chipset 602, display/touch controller(s) 604, communication interface(s) 605, EC/BMC 609, etc.) may be replaced by discrete devices within a heterogeneous computing platform. As such, IHS 600 may assume different form factors including, but not limited to: servers, workstations, desktops, laptops, appliances, video game consoles, tablets, smartphones, etc.

It should be understood that various operations described herein may be implemented in software executed by logic or processing circuitry, hardware, or a combination thereof. The order in which each operation of a given method is performed may be changed, and various operations may be added, reordered, combined, omitted, modified, etc. It is intended that the invention(s) described herein embrace all such modifications and changes and, accordingly, the above description should be regarded in an illustrative rather than a restrictive sense.

Although the invention(s) is/are described herein with reference to specific embodiments, various modifications and changes can be made without departing from the scope of the present invention(s), as set forth in the claims below. Accordingly, the specification and figures are to be regarded in an illustrative rather than a restrictive sense, and all such modifications are intended to be included within the scope of the present invention(s). Any benefits, advantages, or solutions to problems that are described herein with regard to specific embodiments are not intended to be construed as a critical, required, or essential feature or element of any or all the claims.

Unless stated otherwise, terms such as “first” and “second” are used to arbitrarily distinguish between the elements such terms describe. Thus, these terms are not necessarily intended to indicate temporal or other prioritization of such elements. The terms “coupled” or “operably coupled” are defined as connected, although not necessarily directly, and not necessarily mechanically. The terms “a” and “an” are defined as one or more unless stated otherwise. The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system, device, or apparatus that “comprises,” “has,” “includes” or “contains” one or more elements possesses those one or more elements but is not limited to possessing only those one or more elements. Similarly, a method or process that “comprises,” “has,” “includes” or “contains” one or more operations possesses those one or more operations but is not limited to possessing only those one or more operations.

1. A thermally conductive foam cooling system comprising:
a foam block having a surface with a contour that matches the contour of an electrical component; and
a coolant pipe immersed within the foam block, wherein the coolant pipe is configured to pass a coolant fluid through the foam block,
wherein the foam block is thermally conductive to convey heat from the electrical component to the coolant pipe.

2. The thermally conductive foam cooling system of claim 1, wherein the electrical component comprises a plurality of dual inline memory modules (DIMMs).

3. The thermally conductive foam cooling system of claim 2, wherein the coolant pipe has a cross-sectional shape sufficiently thin to fit between the DIMMs.

4. The thermally conductive foam cooling system of claim 2, wherein the coolant pipe comprises a plurality of coolant pipes each configured to be placed between adjacent DIMMs.

5. The thermally conductive foam cooling system of claim 2, wherein the foam block has been formed by pouring an amorphous material over the DIMMs, wherein the amorphous material turns into the foam block after being cured.

6. The thermally conductive foam cooling system of claim 2, further comprising a casing frame that provides a structure for the foam block.

7. The thermally conductive foam cooling system of claim 6, wherein the casing frame is configured with a plurality of slots into which the DIMMs may be inserted.

8. The thermally conductive foam cooling system of claim 1, further comprising an elongated section of graphite tape that is wrapped around the foam block.

9. The thermally conductive foam cooling system of claim 1, wherein the electronic component comprises at least one of a PCIe card or a storage drive.

10. A cooling method comprising:
pouring an amorphous material over an electrical component; and
immersing a coolant pipe within the amorphous material,
wherein when the amorphous material cures into a foam block, the foam block has a surface with a contour that matches the contour of the electrical component.

11. The cooling method of claim 10, further comprising running a coolant fluid through the coolant pipe, wherein the foam block conveys heat from the electrical component to the coolant fluid.

12. The cooling method of claim 10, further comprising pouring the amorphous material over a plurality of dual inline memory modules (DIMMs).

13. The cooling method of claim 12, further comprising immersing a plurality of the coolant pipes between adjacent ones of the DIMMs, wherein each of the coolant pipes have a cross-sectional shape sufficiently thin to fit between the DIMMs.

14. The cooling method of claim 12, further comprising disposing a casing frame around the DIMMs, wherein the casing frame provides a structure for the foam block, wherein the casing frame is configured with a plurality of slots into which the DIMMs may be inserted.

15. The cooling method of claim 10, further comprising wrapping an elongated section of graphite tape around the foam block.

16. A cooling method comprising:
immersing a coolant pipe in a foam sheet having a plurality of edges;
attaching a cover sheet to a portion of the edges of the foam sheet, wherein the attached cover sheet and foam sheet forms a pouch with an opening; and
inserting an electrical component inside of the pouch through the opening.

17. The cooling method of claim 16, further comprising running a coolant fluid through the coolant pipe, wherein the foam block conveys heat from the electrical component to the coolant fluid.

18. The cooling method of claim 16, further comprising pouring an amorphous material over the electrical component to form the foam sheet.

19. The cooling method of claim 16, further comprising forming the coolant pipe from at least one of copper, brass, aluminum, or a flexible polymer material.

20. The cooling method of claim 16, wherein the electronic component comprises at least one of a PCIe card or a storage drive.
